(19) United States
(12) Patent Application Publication
(10) Pub. No.: US 2013/0015915 A1
(43) Pub. Date: Jan. 17, 2013

(54) SEMICONDUCTOR DEVICE

(71) Applicants: Yukio KOMATSU, Kanagawa-ken (JP); Hitoshi Ohta, Kanagawa-ken (JP); Daisuke Awano, Kanagawa-ken (JP)

(72) Inventors: Yukio KOMATSU, Kanagawa-ken (JP); Hitoshi Ohta, Kanagawa-ken (JP); Daisuke Awano, Kanagawa-ken (JP)

(73) Assignee: Kabushiki Kaisha Toshiba, Tokyo (JP)

(21) Appl. No.: 13/547,373

(22) Filed: Jul. 12, 2012

(30) Foreign Application Priority Data
Jul. 14, 2011 (JP) 2011-156163
Feb. 29, 2012 (JP) 2012-043817
Feb. 29, 2012 (JP) 2012-044626

(51) Int. Cl. H01L 25/00

(52) U.S. Cl. 327/564

(57) ABSTRACT

A semiconductor device including: a first pad to receive first and second test commands supplied from the outside; a voltage generator circuit to generate a test target voltage on the basis of the first and second test commands; a second pad to receive first and second monitor voltages supplied from the outside in response to respective of the first and second test commands, the first and second monitor voltages corresponding to respective lower and upper limit voltages of the test target voltage; and a comparator to output a first output signal at one of first and second logical levels by comparing the test target voltage with the first monitor voltage, and to output a second output signal at one of the first and second logical levels by comparing the test target voltage with the second monitor voltage.

### CROSS-REFERENCE TO RELATED APPLICATIONS

This application is based upon and claims the benefit of priority from the prior Japanese Patent Application No. 2011-156163, filed Jul. 14, 2011, No. 2012-044626, filed Feb. 29, 2012, and No. 2012-043817, filed Feb. 29, 2012, the entire contents of which are incorporated herein by reference.

### FIELD

Embodiments described herein relate generally to semiconductor device.

### BACKGROUND

A method for allowing whether memory cells are non-defective or defective from the outside has been known in which, for example, after an address of a defective memory cell is written into a defective address detector circuit, the defective address detector circuit outputs the defective address to a defective address output terminal if an address to be accessed matches the written address of the defective memory cell (see Japanese Patent Application Publication No. 2005-249735, for example).

In addition, for example in a NAND flash memory, various internal voltages are used to do things such as data writing and reading. During the manufacturing of NAND flash memories, a wafer tester monitors whether or not voltages generated as the internal voltages in each NAND flash memory on a wafer fall within their respective specified ranges (see Japanese Patent Application Publication No. 2002-318265, for example).

### BRIEF DESCRIPTION OF THE DRAWINGS

FIG. 1 is a block diagram showing a semiconductor memory device of a first embodiment.

FIG. 2 is a diagram showing the threshold distribution of memory cells of the first embodiment.

FIG. 3 is a block diagram showing the inside of a controller of the first embodiment.

FIG. 4 is a flowchart showing the test operation of the first embodiment.

FIG. 5 is a block diagram showing an example of a semiconductor device of a second embodiment.

FIG. 6 is a circuit diagram showing the configuration of a main part of the semiconductor device shown in FIG. 5.

FIG. 7 is a block diagram showing the configuration of the semiconductor device of the second embodiment.

FIG. 8 is a flowchart for explaining the test operation of the second embodiment.

FIG. 9 is a block diagram showing the test process of the second embodiment.

### DETAILED DESCRIPTION

In general, according to one embodiment, a semiconductor memory device includes: memory cells; a memory cell array including blocks, each block including a plurality of pages, each page including a plurality of the memory cells; a first storage for holding a first repetition count when data is written into a first memory cell belonging to a first column in each of the pages, the first repetition count indicating the number of times the first memory cell has been programmed so far, a second storage for holding a second repetition count when data is written to a second memory cell belonging to a second column different from the first column in the page, the second repetition count indicating the number of times the second memory cell has been programmed so far; and a controller for registering a block, which includes the first memory cell and the second memory cell, as a defective block when a difference between the first repetition count and the second repetition count exceeds a specified value.

According to other embodiment, a semiconductor device includes; a first pad configured to receive first and second test commands supplied from outside; a voltage generator circuit for generating a test target voltage on the basis of the first and second test commands; a second pad configured to receive a first monitor voltage supplied from outside in response to the first test command and a second monitor voltage supplied from outside in response to the second test command, the first monitor voltage corresponding to a lower limit voltage of the test target voltage, the second monitor voltage corresponding to an upper limit voltage of the test target voltage; and a comparator configured to output a first output signal at one of first and second logical levels by comparing the test target voltage supplied from the voltage generator circuit, with the first monitor voltage, the comparator being configured to output a second output signal at one of the first and second logical levels by comparing the test target voltage supplied from the voltage generator circuit, with the second monitor voltage supplied.

### First Embodiment

Next, descriptions will be provided for a first embodiment by referring to the drawings. For the descriptions, the same parts are denoted by the same reference numerals throughout the drawings. In addition, the dimensional ratios in each drawing are not limited to those shown in the drawing.

### [Configuration of Semiconductor Memory Device]

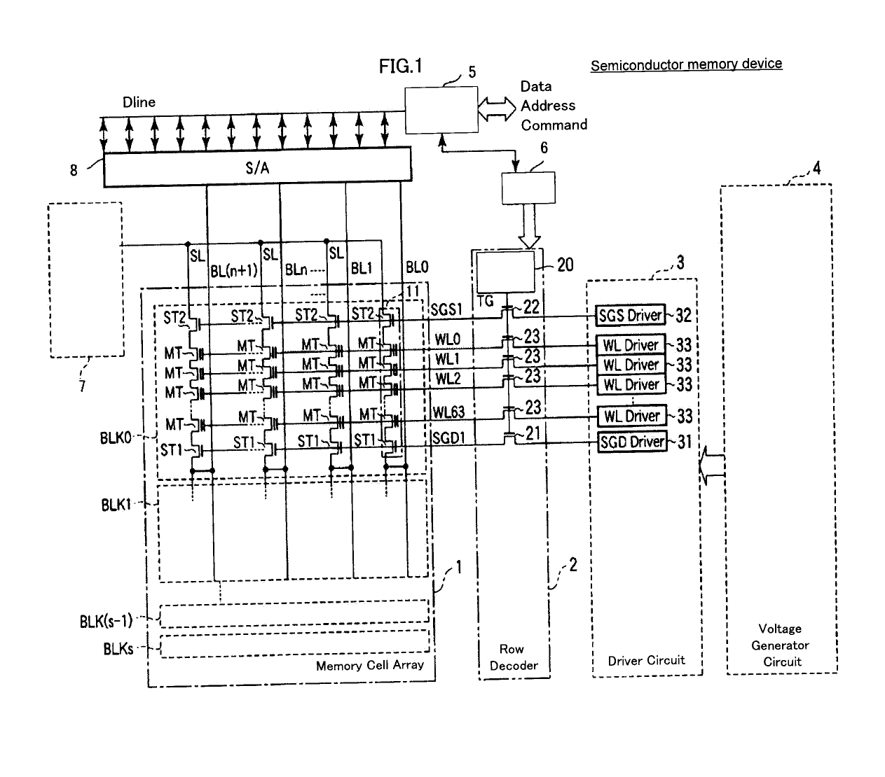

Descriptions will be provided for a semiconductor memory device of the first embodiment by use of the block diagram of FIG. 1.

### 1. Overall Configuration

As shown in FIG. 1, the semiconductor memory device of this embodiment includes a memory cell array 1, a row decoder 2, a driver circuit 3, a voltage generator circuit 4, a data input/output circuit 5, a controller 6, a source line driver circuit 7, and a sensor/amplifier 8.

### 1-1. Example of Memory Cell Array 1

The memory cell array 1 includes a plurality of blocks BLK0 to BLKs (where s is a positive integer) each including multiple nonvolatile memory cells MT. Each of the blocks BLK0 to BLKs includes multiple NAND strings 11 in which nonvolatile memory cells MT are connected together in series. Each NAND string 11 includes, for example, 64 memory cells MT and selector transistors ST1, ST2.

Each memory cell is capable of holding q-level data (where q is a positive integer of 2 or more). This memory cell MT has an FG structure which includes: a floating gate (charge conductive layer) formed on a p-type semiconductor substrate with a gate insulating film interposed in between; and a control gate formed on the floating gate with an inter-gate insulating film interposed in between. It should be noted that the structure of the memory cell MT may be of a MONOS type. The MONOS-type structure is one which includes: a charge storage layer (for example, an insulating film) formed on a semiconductor substrate with a gate insulating film interposed in between; an insulating film (hereinafter referred to as a “block layer”) formed on the charge storage layer, and having a permittivity which is higher than that of the charge storage layer; and a control gate formed on the block layer.

The control gate of the memory cell MT is electrically connected to a word line WL. The drain of the memory cell MT is electrically connected to a bit line BL. The source of the memory cell MT is electrically connected to a source line SL. In addition, the memory cell MT is an n-channel MOS transistor. Incidentally, the number of memory cells MT in each NAND string 11 is not limited to 64, and may be any one of 128, 256, 512 and the like. No specific restriction is imposed on the number of memory cells MT.

Furthermore, each neighboring two of the memory cells MT share the source and drain. Moreover, the memory cells MT are placed between the selector transistors ST1, ST2 in a way that connects their current paths together in series. The drain region in one end of the memory cells MT connected together in series is connected to the source region of the selector transistor ST1, and the source region in the other end of the memory cells MT connected together in series is connected to the drain region of the selector transistor ST2.

The control gates of the memory cells MT in the same row are commonly connected to one of the word lines WL0 to WL63. The gate electrodes of the selector transistors ST1, for the memory cells MT, in the same row are commonly connected to a selection gate line SGD1, and the gate electrodes of the selector transistors ST2, for the memory cells MT, in the same row are connected to a selector gate line SGS1. It should be noted that for the purpose of making the following descriptions simple, any one of the word lines WL0 to WL63 will be simply referred to as a “word line WL” from time to time if there is no need to identify which of the word lines WL0 to WL63 it is. In addition, the drains of the selector transistors ST1 in the same column in the memory cell array 1 are commonly connected to one of the bit lines BL1 to BL(n+1). Similarly, any one of the bit lines BL1 to BL(n+1) will be hereinafter generically referred to as a “bit line BL” if there is no need to identify which of the bit lines BL1 to BL(n+1) it is (where n is a positive integer). The sources of the selector transistors ST2 are commonly connected to the source line SL.

Furthermore, data is written into the multiple memory cells MT connected to the same word line BL in batches. This unit of writing in batches is referred to as a page. In addition, data is erased from the multiple memory cells MT in the same block BLK in batches.

For the sake of explanatory convenience, among the multiple memory cells MT connected to the same word line WL which constitute one page, a memory cell MT situated nearest to the row decoder 2 (whose details will be described later) is referred to as a “first memory cell,” and a memory cell MT situated farthest from the row decoder 2 is referred to as a “second memory cell.” In the case shown in FIG. 1, the first memory cell is that whose drain is electrically connected to the bit line BL, and the second memory cell is that whose drain is electrically connected to the bit line BL(n+1).

Similarly, a group of memory cells situated nearest to the row decoder 2 is referred to as a “first memory cell group,” and a group of memory cells situated farthest from the row decoder 2 is referred to as a “second memory cell group.” In the case shown in FIG. 1, the first memory cell group includes memory cells whose respective drains are electrically connected to the bit lines BL0 to BL3, and the second memory cell group includes memory cells whose respective drains are electrically connected to the bit lines BL(n−1) to BL(n+1).

### 1-2. Threshold Distribution of Memory Cells MT

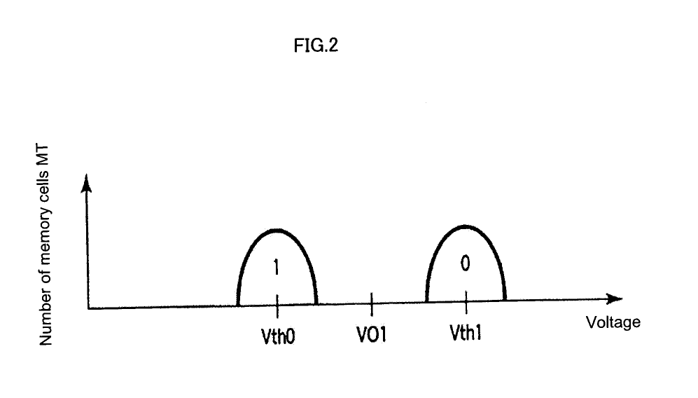

Descriptions will be provided for the threshold distribution of the memory cells MT by using FIG. 2. FIG. 2 is a graph in which: the axis of abscissa represents the threshold distribution (voltage); and the axis of ordinate represents the number of memory cells MT.

As shown, each memory cell MT is capable of holding, for example, 2-level data (1-bit data). In other words, each memory cell MT is capable of holding either of the two types of data which represent “1” and “0” in an ascending order of the threshold voltage Vth.

The threshold voltage Vth0 representing “1” data in the memory cell MT is expressed with Vth0<V01. The threshold voltage Vth1 representing “0” data in the memory cell MT is expressed with V01<Vth1. In this manner, the memory cell MT is designed to be capable of holding the 1-bit data, which is either “0” data or “1” data depending on the threshold value. In an erased state, the memory cell MT is set at “1” data (for example, a negative voltage). When data is written into the memory cell MT, or when charges are injected into the charge storage layer, the memory cell MT is set at a positive threshold voltage.

### 1-3. Row Decoder 2

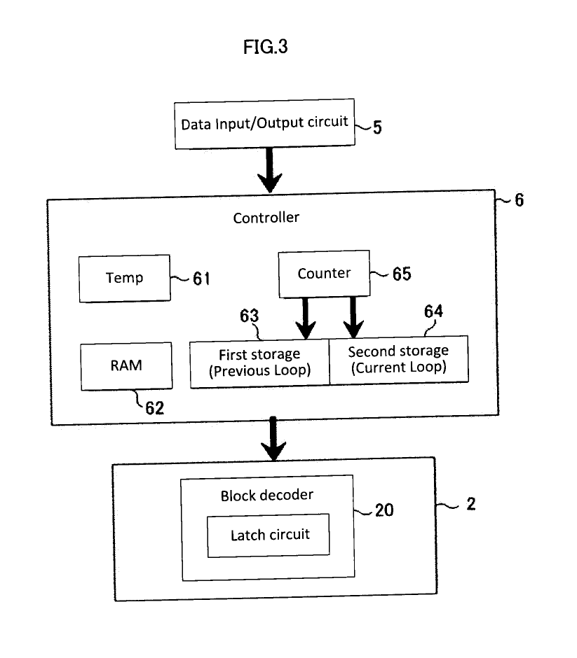

Return to FIG. 1, descriptions will be provided for the row decoder 2. The row decoder 2 includes a block decoder 20, and transfer transistors (N-channel MOS transistors) 21 to 23. For a data-write operation, a data-read operation and a data-erase operation, the block decoder 20 decodes a block address given by the controller 6, and selects a block BLK on the basis of a result of the decoding. This block decoder 20 is provided to each block BLK. As shown in FIG. 3, each block decoder 20 has a latch circuit. The latch circuit holds data indicating whether or not the block BLK corresponding to the block decoder 20 is a defective block. A block selection signal is transferred from the block decoder 20 to the transfer transistors 21 to 23. By this, the transfer transistors 21 to 23 are put into the ON state. Thereby, on the basis of the block selection signal given by the block decoder 20, the row decoder 2 transfers voltages, which are given by the driver circuit 3, to the selection gate lines SGD1, SGS2, and the word lines WL0 to WL63, respectively.

Furthermore, the row decoder 2 decodes a row address given by the controller 6, and selects a desired word line WL out of the multiple word lines WL in a selected block on the basis of a result of the decoding.

### 1-4. Driver Circuit 3

The driver circuit 3 includes: selection gate line drivers 31, 32 provided to the respective selection gate lines SGD1, SGS1; and word line drivers 33 provided to the respective word lines WL. In this embodiment, the word line drivers 33 and the selection gate line drivers 31, 32 are provided to each of the blocks BLK0 to BLKs.

For the data-write operation, the data-read operation and the data-erase operation, as well as for a data-verification operation, the selection gate line driver 31 transfers, for example, a signal sgd to the gates of the selection transistors ST1 via the selection gate line SGD1. Incidentally, when the signal sgd is at the “L” level, the voltage of the signal sgd is set at 0 volts; and when the signal sgd is at the “H” level, the voltage of the signal sgd is set equal to a voltage VDD (for example, 1.8 volts).

Moreover, like the selection gate line driver 31, the selection gate line driver 32 transfers, for example, a signal sgs to the gates of the selection transistors ST2 via the selection gate line SGS1 of the selected block BLK for the data-write operation, the data-read operation, and the data-verification operation. Incidentally, when the signal sgs is at the “L” level, the voltage of the signal sgs is set at 0 volts; and when the signal sgs is at the “H” level, the voltage of the signal sgd is set equal to the voltage VDD.

### 1-5. Voltage Generator Circuit 4

The voltage generator circuit 4 generates voltages needed for programming, reading and erasing data by boosting or dropping a voltage given from the outside. Thereafter, the voltage generator circuit 4 supplies the thus-generated voltages to the driver circuit 3.

### 1-6. Data Input/Output Circuit 5

The data input/output circuit 5 outputs addresses (a row address, a column address and a block address; in this respect, the combination of the row address and the column address is referred to as a page address) and a command, which are supplied from outside (for example, an external host) via an I/O terminal which is not illustrated, to the controller 6. In addition, the data input/output circuit 5 outputs write data to the sensor/amplifier 8 via a data line Dline.

In addition, when outputting data read from the memory cell array 1 to the host, the data input/output circuit 5 receives the data, which is amplified by the sensor/amplifier 8, via the data line Dline, and outputs the data to the host via the I/O terminal, on the basis of the control by the controller 6.

### 1-7. Controller 6

The controller 6 controls the operations of the whole NAND flash memory. To put it specifically, on the basis of the addresses and the command given by the host via the data input/output circuit 5, the controller 6 carries out operation sequences for the data-write operation, the data-read operation and the data-erase operation. On the basis of the addresses and the operation sequences, the controller 6 generates a block selection signal, a column selection signal and a row selection signal.

The controller 6 outputs the block selection signal and row selection signal, which have been mentioned above, to the row decoder 2. Furthermore, the controller 6 outputs the column selection signal to a column decoder (whose illustration is omitted). In this respect, the column selection signal is a signal for selecting a column direction in the sensor/amplifier 8.

Moreover, the controller 6 is given a control signal which is supplied from a memory controller connected to the semiconductor storage device. On the basis of the thus-supplied control signal, the controller 6 discriminates whether the signal supplied to the data input/output circuit 5 from the host via the I/O terminal represents addresses or data.

As shown in FIG. 3, the controller 6 includes a temporary storage device (Temp) 61, a RAM 62, a first storage 63, a second storage 64 and a counter 65.

The temporary storage device (Temp) 61 holds a specified value S during a test operation. This specified value S is an index for making write-operation characteristics fall within a tolerance range in each page despite manufacturing variations. In other words, variations in the write-operation characteristics among the memory cells MT connected to the same word line WL are made to fall within the tolerance range by use of the specified value S. The specified value S is supplied from outside when the test operation which will be described later is carried out. Because, for example, the specified value S varies from one product to another, the optimal specified value S is supplied from outside.

A block including a first memory cell and its corresponding second memory cell is registered as a defective block when L1 and L2 satisfy an expression

|L1−L2|>S Expression (1)

where: a program count indicating the number of times the first memory cell has been programmed is denoted by L1; and a program count indicating the number of times the second memory cell has been programmed is denoted by L2. The specified value S is a value used to judge whether or not a block is a defective block as well.

The RAM 62 is a work area. The area in the RAM 62 is used when, for example, arithmetic is performed on the above-mentioned expression (1) by using data held in, for example, the temporary storage device 61, the first storage 63 and the second storage 64.

The first storage 63 holds the program count (L1) of the first memory cell. The first storage 63 holds the number of times program operations and verification operations have been so far repeated, when data is written into the first memory cell.

The second storage 64 holds the program count (L2) of the second memory cell. The second storage 64 holds the number of times program operations and verification operations have been so far repeated, when data is written into the second memory cell.

The counter 65 has a function of counting the number of times the program operations and the verification operations have been so far repeated, when data is written into the first memory cell and the second memory cell. For example, in an initialized state, the counter 65 holds count data indicating the count is “1.” The counter 65 increments the count data by one, every time a verification fails. When the verification passes, the count data updated by the counter 65 is transferred to the first storage 63 or the second storage 64.

### 1-8. Sensor/Amplifier 8

The sensor/amplifier 8 senses and amplifies data which is read from a memory cell MT to the bit line BL when data is read. To put it specifically, after the bit line BL is pre-charged at a predetermined voltage, the voltage is discharged from the bit line BL via a NAND string 11 which is selected by the row decoder 2, and thereby, the sensor/amplifier 8 senses how the voltage is discharged from the bit line BL. In other words, the sensor/amplifier 8 amplifies the voltage of the bit line BL, and thereby senses the data held in the memory cell MT.

In addition, for the data-write operation, the write data is transferred to the corresponding bit line BL.

### 1-9. Column Decoder

The column decoder (whose illustration is omitted) decodes the column address which is given by the controller 6, and outputs the column selection signal to the sensor/amplifier 8. On the basis of this column selection signal, a desired latch circuit in the sensor/amplifier 8 is selected.

### 1-10. Address Buffer

An address buffer (whose illustration is omitted) has a function of holding an address which is inputted into the controller 6. Incidentally, although in the semiconductor storage device of this embodiment, the address is supplied to the address buffer via the controller 6, the present invention is not limited to this. Instead, the address may be designed to be supplied directly from the data input/output circuit 5.

### [How Semiconductor Storage Device Operates]

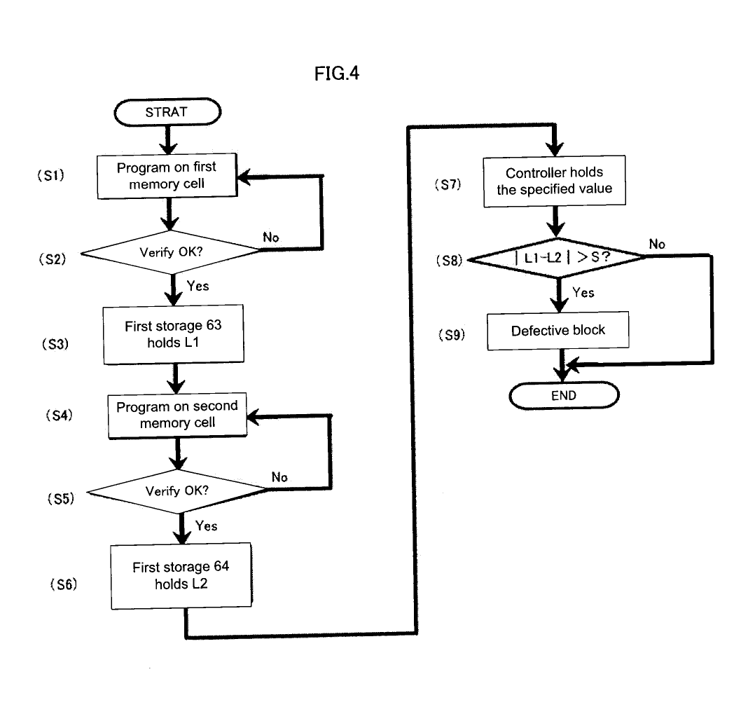

Next, descriptions will be provided for the test operation of the semiconductor storage device of this embodiment by use of FIG. 4. This test operation is carried out when, for example, a die sort test is conducted. The test operation of this embodiment aims at registering a block BLK, which includes a page satisfying the expression (1), as a defective block.

First of all, in step S1, a program is executed on a first memory cell. The “0” data is programmed in the first memory cell in a selected page, and the “1” data is programmed in the other memory cells in the same selected page. On the basis of the data, addresses and program command received from the outside, the controller 6 sets the data and the desired column address in the sensor/amplifier 8. The controller 6 sets the desired row address in the row decoder 2. Thereafter, on the basis of the program command, the controller 6 executes the program.

In step S2, the verification operation is performed on the first memory with respect to the “0” data. For example, when the Sensor/Amplifier is a voltage-sensor-type, the bit line BL connected to the first memory cell is pre-charged. Thereafter, conduction is established between the bit line BL and a temporary data cache (TDC) in the sensor/amplifier 8, and charge transfer is caused. On the basis of the potential of the temporary data cache (TDC), a judgment is made on whether the verification passes or fails. Although an example of the verification operation has been shown, the verification operation is not limited to this. Instead, another mode of verification operation may be employed.

If it is judged that the verification fails, the process returns to step S1. At this time, the count data in the counter 65 is incremented simultaneously as well. The verification operation is repeated until it is judged that the verification passes (if Yes in step S2).

In step S3, the program count (L1) of the first memory cell at the time when the verification passes (Yes in step S2) is transferred to the first storage 63. As a result, the first storage 63 holds the program count (L1) of the first memory cell.

In steps S4 through S6, the operations which are the same as those in steps S1 through S3 are performed on the second memory cell.

To put it specifically, in step S4, the program is executed on the second memory cell in the same page as is the first memory cell. The “0” data is programmed in the second memory cell in the selected page, and the “1” data is programmed in the other memory cells in the same selected page. In step S5, the verification operation is performed on the second memory cell with respect to the “0” data. If it is judged that the verification fails, the process returns to step S4. At this time, the count data in the counter 65 is incremented simultaneously as well. The verification operation is repeated until it is judged that the verification passes (Yes in step S5). In step S6, the program count (L2) of the second memory cell at the time when the verification passes (Yes in step S5) is transferred to the second storage 64. As a result, the second storage 64 holds the program count (L2) of the second memory cell.

In step S7, the controller 6 holds the specified value S. In other words, the controller 6 holds the specified value S, which is received via the data input/output circuit 5, in the temporary storage device 61.

In step S8, the controller 6 reads the specified value S held in its internal temporary storage device 61, L1 held in its internal first storage 63, and L2 held in its internal second storage 64 to the RAM 62. Thereby, the controller 6 judges whether or not the specific value S, L1 and L2 satisfy the expression (1).

If in a particular page, the relationship among the number L1 of times the first memory cell has been programmed, the number L2 of times the second memory cell has been programmed, and the specified value S satisfy the expression (1) (if Yes in step S8), the controller 6 judges that a block including the page is a defective block.

The controller 6 holds data (for example, “0” data), indicating that the block including the page is the defective data, in a latch circuit (provided in the block decoder 20) corresponding to the block including the page for the purpose of enabling the block including the page to be recognized as the defective block (in step S9). Then, the controller 6 terminates the process.

On the other hand, if in a particular page, the relationship among the number L1 of times the first memory cell has been programmed, the number L2 of times the second memory cell has been programmed, and the specified value S do not satisfy the expression (1) (if No in step S8), the controller 6 terminates the process without doing anything else.

### Effects of First Embodiment

It is possible to provide the semiconductor memory device whose reliability can be improved.

As the NAND flash memory becomes smaller in size, the influence of the production variation on the performance and characteristics of the product becomes more obvious. As a result, this makes it difficult to make the characteristics uniform among the memory cells in the NAND flash memory, and accordingly makes it likely that the reliabilities of the memory cells decrease.

In the semiconductor memory device of the present invention, if the relationship among the number L1 of times the first memory cell has been programmed, the number L2 of times the second memory cell has been programmed, and the specified value S satisfy the expression (1) (if Yes in step S8), the controller 6 judges that the block including the page is a defective block. This makes it possible to detect the production variation in the memory cells connected to the same word line WL (among the columns in the same page). As a result, only blocks each in which the production variation among the memory cells connected to the same word line WL (among the columns in the same page) is small can be used, for example, as a user area (an area for holding ordinary data) by rejecting the block including the page in which the specified value S satisfies the desired expression (1) as the defective block. Accordingly, the semiconductor memory device of the present invention enables the reliabilities of the memory cells to be improved compared with a semiconductor memory device: for which such a judgment is not made; and in which the defective block is not defined.

### Modification 1

A semiconductor memory device of Modification 1 is different from the semiconductor memory device of the first embodiment in terms of the selection of the first memory cell and the second memory cell.

In Modification 1, it is desirable that among the memory cells MT connected to the same word line WL in each page, a memory cell situated in one end (a memory cell whose drain is connected to the bit line BL0 in FIG. 1) should be defined as the first memory cell; and a memory cell situated in the other end in the same page (a memory cell whose drain is connected to the bit line BL(n+1) in FIG. 1) should be defined as the second memory cell. The production variation in an entire page can be detected better by the comparison between the program counts of the memory cells situated in the two ends in the page than by the comparison between the program counts of two memory cells not situated in the two ends in the page. As a result, Modification 1 makes it possible to enhance the reliabilities of the memory cells.

### Modification 2

A semiconductor memory device of Modification 2 is different from the semiconductor memory device of the first embodiment in that the production variation is detected by using the first memory cell group and the second memory cell group.

To put it specifically, a group of memory cells situated nearest to the row decoder 2 is referred to as the first memory cell group, and a group of memory cells situated farthest from the row decoder 2 is referred to as the second memory cell group. In the case shown in FIG. 1, the memory cells whose drains are electrically connected to the bit lines BL0 to BL3 constitute the first memory cell group, and the memory cells whose drains are electrically connected to the bit lines BL(n−1) to BL (n+1) constitute the second memory cell group.

In the first embodiment and Modification 1, the program count is detected in each of the first memory cell and the second memory cell. In the semiconductor memory device of Modification 2, the program count is detected in each of the first memory cell group and the second memory cell group. For this reason, Modification 2 can enhance the reliability with higher accuracy than the first embodiment and Modification 2.

### Second Embodiment

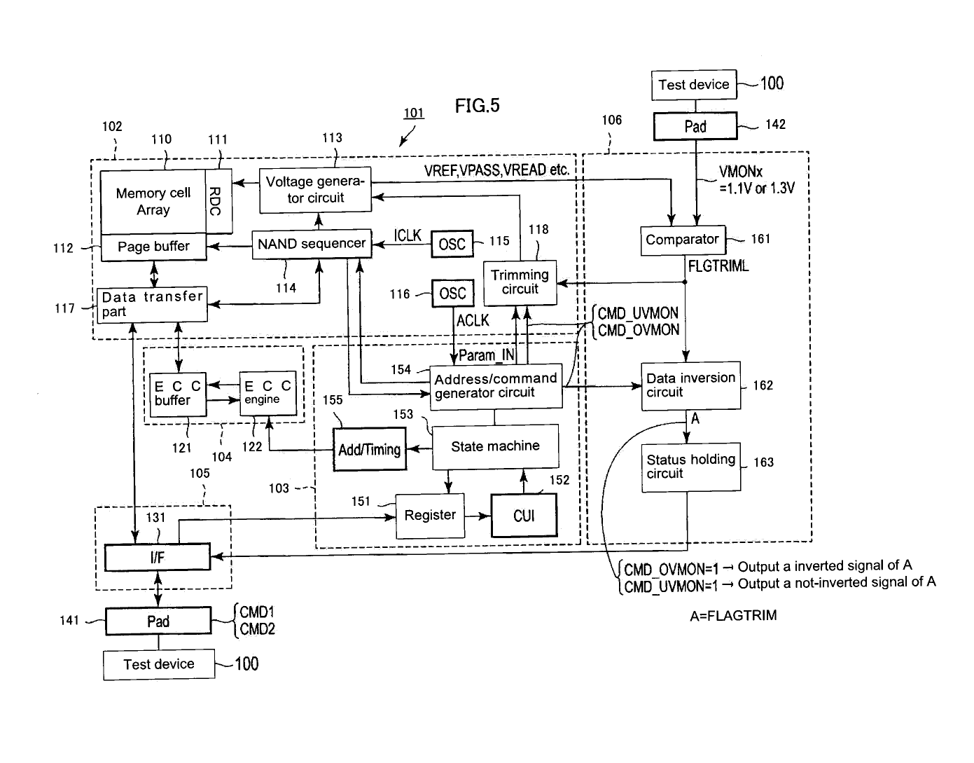

Descriptions will be hereinbelow provided for a second embodiment by referring to the drawings. FIG. 5 shows an example of a semiconductor device of this embodiment, which is applied to a NAND flash memory.

In FIG. 5, a semiconductor device 101 includes a NAND flash memory 102, a controller 103, an ECC (Error Checking and Correcting) section 104, an interface section 105 and a test circuit 106.

### <NAND Flash Memory 102>

The NAND flash memory 102 includes a memory cell array 110, a row decoder (RDC) 111, a page buffer 112, a voltage generator circuit 113, a NAND sequencer 114, oscillators (OSC) 115, 116, a data transfer part 117 and a trimming circuit 118.

The memory cell array 110 includes multiple NAND strings each including multiple memory cells, which are not illustrated. Each of these NAND strings includes, for example, the multiple memory cells connected together in series, and two selection gate transistors connected together with the multiple memory cells interposed in between. These memory cells are designed to be capable of being selected by use of multiple word lines, selection gate lines and bit lines which are not illustrated.

For a data-write operation, a data-read operation and a data-erase operation, the row decoder 111 selects particular ones from the word lines and selection gate lines, and transfers predetermined voltages to the selected word lines and the selection gate lines.

The page buffer 112 has a function of sensing and holding data which has the same size as one page in the memory cell array 110 does. To put it specifically, for the data-read operation, the page buffer 112 temporarily stores a page of data which has been read out from the memory cell array 110; and for the data-write operation, the page buffer 112 temporarily stores a page of data to be written into the memory cell array 110.

It should be noted that, for example, the NAND flash memory carries out the data-read operation and the data-write operation by handling each group of multiple memory cells sharing the same word line as a page.

In addition, for the data-read operation, the page buffer 112 transfers, for example a 64-bit piece of data designated by an address, which is part of a page of data, to the data transfer part 117. For the data-write operation, the page buffer 112 receives the 64-bit piece of data from the data transfer part 117. Furthermore, the page buffer 112 includes a sensor/amplifier, albeit not illustrated, for: writing write data into the memory cell array 110; and reading out data from the memory cell array 110.

The voltage generator circuit 113 generates voltages (VREF, VPASS, VREAD, VPRG, VERA and the like) needed for the data-write operation, the data-read operation and the data-erase operation, and supplies these voltages to the row decoder 111 and the like.

The NAND sequencer 114 controls the operation of the NAND flash memory 102 as a whole. To put it specifically, once receiving various commands from the controller 103, the NAND sequencer 114 carries out sequences for the data-write operation, the data-read operation and the data-erase operation in response to the commands. Moreover, the NAND sequencer 114 controls the operation of the voltage generator circuit 113 and the operation of the page buffer 112 in accordance with the various sequences.

The oscillator 115 generates an internal clock ICLK, and supplies this internal clock ICLK to the NAND sequencer 114. The NAND sequencer 114 operates in synchronism with this internal clock ICLK. In addition, the NAND sequencer 114 generates some clock signals from the internal clock ICLK, and supplies these clock signals to the data transfer part 114.

The oscillator 116 generates another internal clock ACLK, and supplies this internal clock ACLK to the controller 103. The internal clock ACLK is a reference clock for the operation of the controller 103.

The data transfer part 117 controls the transfer of data between the page buffer 112 and the ECC section 104, as well as the transfer of data between the page buffer 112 and the interface section 105. For these controls, the data transfer part 117 includes multiple buses and multiple latch circuits, which are not illustrated.

The trimming circuit 118 controls the voltages to be generated by the voltage generator circuit 113, and includes a register, albeit not illustrated, for holding multiple pieces of numerical data, as parameters, which are beforehand set up in association with the voltages to be generated. Once receiving the supply of a command from an address/command generator circuit 154, the trimming circuit 118 selects a piece of numerical data which corresponds to the command, and supplies the selected piece of numerical data to the voltage generator circuit 113. On the basis of the supplied piece of numerical data, the voltage generator circuit 113 generates a voltage.

### <ECC Section 104>

When reading out data from the NAND flash memory 102, the ECC section 104 detects and corrects errors in the read data. In addition, when writing data into the NAND flash memory 102, the ECC section 104 generates parity data for the data to be programmed. The ECC section 104 includes an ECC buffer 121 and an ECC engine 122.

The EEC buffer 121 is connected to the data transfer part 117 through a NAND data bus. The ECC buffer 121 temporarily stores data for the purpose of ECC processes (error correction for the data-read operation, and parity data generation for the programming operation). The ECC buffer 121 is connected to the data transfer part 117 through, for example, a 32-bit-wide data bus.

The ECC engine 122 performs the ECC processes using data which are stored in the ECC buffer 121. To put it specifically, the ECC engine 122 corrects errors in the data which is inputted into the ECC buffer 121, and outputs the corrected data to the ECC buffer 121 again.

In sum, for the data-write operation, the ECC section 104 generates the parity data for the data which is transferred from the interface section 105 to the page buffer 112. In addition, for the data-read operation, the ECC section 104 detects and corrects errors in the data which is read out from the memory cell array 110 and is transferred to the page buffer 112.

### <Interface Section 105>

The interface section 105 includes, for example, an interface (I/F) 131.

The interface 131 receives and transfers various signals, such as data, control signals, commands and addresses, from and to host equipment and a test device 100, which will be described later, outside the semiconductor device 101 via a pad 141. Examples of the control signals include: a chip enable signal /CE for enabling the entirety of the semiconductor device 101; an address valid signal /AVD for latching an address; a clock CLK for a burst-read operation; a write enable signal /WE for enabling a data-write operation; an output enable signal /OE for enabling the output of data to the outside. Furthermore, the interface 131 sends control signals concerning a write request and a read request to the controller 103.

Moreover, for the test operation which will be described later, the interface 131 receives commands which are supplied from the test device 100 via the pad 141, and sends the commands to the controller 103. In addition, the interface 131 sends a status signal, which is outputted from a test circuit 106, to the test device 100 via the pad 141.

### <Controller 103>

The controller 103 controls the operation of the entirety of the semiconductor device 101. The controller 103 includes a register 151, a command/user interface (CUI) 152, a state machine 153, the address/command generator circuit 154, and an address/timing generator circuit (Add/Timing) 155.

The register 151 holds, for example, a read command, a write command and a test command, which are supplied from the interface 131.

Once the predetermined commands are held in the register 151, the command/user interface 152 recognizes that a function execution command has been given to the semiconductor device 101, and thus sends an internal command signal to the state machine 153.

On the basis of the internal command signal supplied from the command/user interface 152, the state machine 153 controls the sequence operation in the semiconductor device 101. The functions supported by the state machine 153 are many, including a write function, a read function and an erase function. The state machine 153 controls the operation of the NAND flash memory 102 in order for these functions to be executed.

On the basis of the control by the state machine 153, the address/command generator circuit 54 controls the operation of the NAND flash memory 102. To put it specifically, in synchronism with the internal clock ACLK supplied from the oscillator 116, the address/command generator circuit 154 generates an address, commands (Write/Read/Load) and the like for controlling the operation of the NAND flash memory 102, and sends the address, the commands (Write/Read/Load) and the like to the NAND sequencer 114.

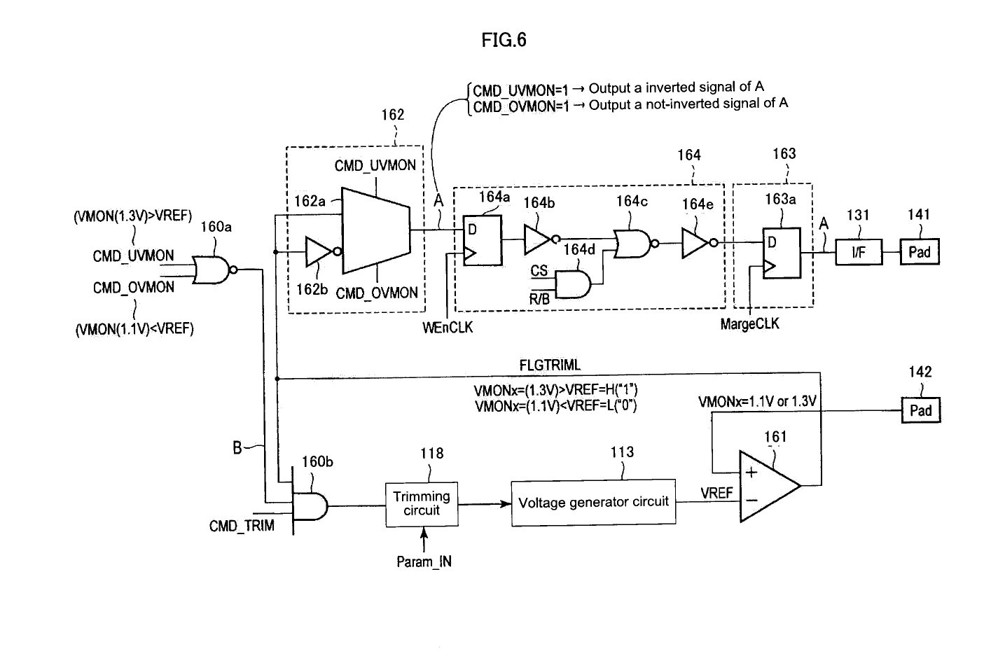

In addition, when causing the voltage generator circuit 113 to generate the voltages, the address/command generator circuit 154 generates commands CMD_UVMON, CMD_OVMON. The address/command generator circuit 154 supplies the commands CMD_UVMON, CMD_OVMON to the trimming circuit 118 and a data inversion circuit 162. When the command CMD_OVMON is a signal representing “0,” the trimming circuit 118 boosts the voltages to be generated by the voltage generator circuit 113. When the command CMD_UVMON is a signal representing “0,” the trimming circuit 118 drops the voltages to be generated by the voltage generator circuit 113. Incidentally, their details will be given by use of FIG. 6.

Furthermore, at the time of a test of the voltage generator circuit 113 which will be described later, both of the commands CMD_UVMON, CMD_OVMON are set at “1.” Thereby, the operation of the trimming circuit 113 is halted, and the trimming circuit 113 generates voltages, which are selected by the commands for the test, without trimming. Incidentally, their details will be given by use of FIG. 6.

The address/timing generator circuit 155 controls the operation of the ECC engine 122 on the basis of the control by the state machine 153. To put it specifically, the address/timing circuit 55 issues the addresses and commands which are needed for the ECC engine 122, and supplies these addresses and commands to the ECC engine 122.

### <Test Circuit 6>

During the process of manufacturing the semiconductor device, the test circuit 106 tests whether or not the voltages generated by the voltage generator circuit 113 fall within their specified scopes, and outputs the test results. When the test is conducted, a wafer in which the semiconductor device 101 is formed is attached to the test device 100, and the probes of the test device 100, which are not illustrated, are brought into contact with the pads 141, 142 of the semiconductor device 101. In this state, the test device 100 supplies commands showing the contents of the test to the pad 141, and the reference voltages corresponding to the commands to the pad 142.

As described later, the test device 106 compares the test voltages (VREF, VPASS, VREAD and the like shown in FIG. 5), which are generated by the voltage generator circuit 113 in accordance with the commands, with monitor voltages VMONx, and outputs status signals, each of which shows whether or not the corresponding one of the test voltages generated by the voltage generator circuit 113 falls within its specified scope, to the test device 100.

To put it specifically, the test circuit 106 includes a comparator 161, the data inversion circuit 162, and a status holding circuit 163.

The comparator 161 compares the monitor voltages VMONx as the reference voltages supplied to the test pad 142, with each (for example, VREF) of the voltages generated by the voltage generator circuit 113, which should be tested (hereinafter referred to as “test target voltage”). The monitor voltages VMONx are changed by the test device 100 corresponding to the test target voltage generated by the voltage generator circuit 113. The monitor voltages VMONx indicate, for example, the upper and lower limit values of the voltage generated by the voltage generator circuit 113 in accordance with the commands (hereinafter also referred to as the “upper limit monitor voltage VMONx and lower limit monitor voltage VMONx,” respectively). When the voltage (for example, VREF) generated by the voltage generator circuit 113 is, for example, 1.2V, the upper limit monitor voltage VMONx is set at, for example, 1.3V, and the lower limit monitor voltage VMONx is set at, for example, 1.1V.

It should be noted that although in this embodiment, the monitor voltages VMONx are described as indicating the upper and lower limit values of the voltage generated by the voltage generator circuit 113 in accordance with the commands, the monitor voltages VMONx are not limited to this case. For example, when the voltage (for example, VREF) generated by the voltage generator circuit 113 is, for example, 1.2V, the first monitor voltage VMONx is set at, for example, 1.2V; and the second motor voltage VMONx is set at an upper limit voltage (for example, 1.3V) of the tolerance range when the voltage generated by the voltage generator circuit 113 is higher than the first monitor voltage, and at a lower limit voltage (for example, 1.1V) of the tolerance range when the voltage generated by the voltage generator circuit 113 is lower than the first monitor voltage.

For example, first of all, the comparator 161 compares the lower limit monitor voltage VMONx with the voltage VREF generated by the voltage generator circuit 113, and subsequently compares the upper limit monitor voltage VMONx with the voltage VREF generated by the voltage generator circuit 113. To put it specifically, if the voltage VREF generated by the voltage generator circuit 113 is higher than the lower limit monitor voltage VMONx (1.1V), the comparator 161 outputs the low level (“0”) as an output signal FLGTRIML; and if the voltage VRER generated by the voltage generator circuit 113 is lower than the upper limit monitor voltage VMONx (1.3V), the comparator 61 outputs the high level (“1”) as the output signal FLGTRIML.

VMONx (1.1V)<VREF=“0”

VMONx (1.3V)>VREF=“1”

The output signal FLGTRIML from the comparator 161 is supplied to the trimming circuit 118 and the data inversion circuit 162. During the test, as described later, the trimming circuit 118 is halted when the internal command CMD_UVMON supplied from the address/command generator circuit 154 is at the high level, and when the command CMC_OVMON supplied from the address/command generator circuit 154 is at the high level.

The internal command CMD_UVMON is that which is used to compare the upper limit monitor voltage VMONx with the voltage VREF generated by the voltage generator circuit 113, and the internal command MD_OVMON is that which is used to compare the lower limit monitor voltage VMONx with the voltage VREF generated by the voltage generator circuit 113.

In addition, when the internal command CMD_UVMON is at the high level, the data inversion circuit 162 outputs the output signal FLGTRIML from the comparator 161 as it is. When the internal command CMD_OVMON is at the high level, the data inversion circuit 162 inverts the output signal FLGTRIML from the comparator 161, and outputs the inverted signal. To put it specifically, when the output signal FLGTRIML from the comparator 61 is the signal representing “0” on the basis of VMONx (1.1V)<VREF which is a result of the comparison by the comparator 161 between the lower limit monitor voltage VMONx and the voltage VREF generated by the voltage generator circuit 113, the data inversion circuit 162 inverts this signal representing “0,” and outputs a signal representing “1.” The output signal from the data inversion circuit 162 is once held in the status holding circuit 163, and is supplied to the test device 100 via the interface 131 and the pad 141.

FIG. 6 shows a specific example of the test circuit 106. In FIG. 6, components which are the same as those shown in FIG. 5 are denoted by the same reference signs.

In FIG. 6, the internal commands CMD_UVMON, CMD_OVMON outputted from the address/command generator circuit 154 are supplied to the respective input terminals of an NAND circuit 160a. The output terminal of the NAND circuit 160a is connected to an input terminal of an AND circuit 160b.

The output terminal of the comparator 161 is connected to another input terminal of the AND circuit 160b. For example, an internal command CMD_TRIM for controlling the trimming circuit is supplied to the input terminal of the AND circuit 160b. This internal command CMD_TRIM is generated by the address/command generator circuit 154 shown in FIG. 5. The output terminal of the AND circuit 160b is connected to the input terminal of the trimming circuit 118. The output terminal of the trimming terminal 118 is connected to the input terminal of the voltage generator circuit 113.

During the test, the internal commands CMD_UVMON, CMD_OVMON both are set at the high level. For this reason, the output signal from the NAND circuit 160a is at the low level. Accordingly, the input condition of the AND circuit 160b is not satisfied, and the trimming circuit 118 halts its trimming operation. At this time, on the basis of a signal Param_IN supplied from the address/command generator circuit 154, the trimming circuit 118 supplies the voltage generator circuit 113 with numerical data for generating test target voltages corresponding to the commands CMD1, CMD2. Thus, during the test, the voltage generator circuit 113 generates the test target voltages corresponding to the commands CMD1, CMD2. In other words, because either the internal command CMD_UVMON or the internal command CMD_OVMON is at the high level during the test, the trimming circuit 118 does not operate. However, because a result of the trimming is latched in the trimming circuit 118 in advance, the voltage generator circuit 113 outputs a voltage, which corresponds to the result of the trimming, to the comparator 161 during the test.

The output terminal of the voltage generator circuit 113 is connected to a first input terminal of the comparator 161. A second input terminal of the comparator 161 is connected to the pad 142. The output terminal of the comparator 161 is connected to the AND circuit 160b, and to the data inversion circuit 162.

This data inversion circuit 162 is formed from a two-input selection circuit 162a and an inverter circuit 162b. The output signal from the comparator 161 is connected to a first input terminal of the selection circuit 162a, and is connected to a second input terminal of the selection circuit 162a via the inverter circuit 162b. The selection terminal 162a selects a signal to be supplied to the first input terminal on the basis of the internal command CMD_UVMON, and selects a signal to be supplied to the second input terminal on the basis of the internal command CMD_OVMON. For these reasons, the signal to be selected on the basis of the internal command CMD_UVMON is outputted without being inverted, while the signal to be selected on the basis of the internal command CMD_OVMON is outputted by being inverted by the inverter circuit 162b.

As the output signal from the data inversion circuit 162, a status signal A is supplied to a timing circuit 164. This timing circuit 164 includes, for example, a flip-flop circuit 164a, an inverter circuit 164b, a NOR circuit 164c, an AND circuit 164d and an inverter circuit 164e.

The flip-flop circuit 164a holds the status signal A in accordance with a clock signal WEnCLK. The clock signal WEnCLK is generated on the basis of, for example, the internal clock ICLK outputted from the oscillator 115. The output signal from the flip-flop circuit 164a is supplied to a first input terminal of the NOR circuit 164c via the inverter circuit 164b.

In addition, a ready/busy signal (R/B) for indicating whether the semiconductor device 101 is ready or busy, and for example, a chip status signal CS for indicating which state the semiconductor device 101 is in are supplied to the input terminal of the AND circuit 164d. The output signal from the AND circuit 164d is supplied to a second input terminal of the NOR circuit 164c. The output signal from the NOR circuit 164c is supplied to the status holding circuit 163 via the inverter circuit 164e.

The status holding circuit 163 is formed from a flip-flop circuit 163a which operates on the basis of, for example, a clock signal MargeCLK. The status signal outputted from the inverter circuit 64e is held by this flip-flop circuit 163a. The output terminal of the flip-flop circuit 163a is connected to the interface 131, and this interface 131 is connected to the pad 141. The clock signal MargeCLK is generated on the basis of, for example, the internal clock ICLK outputted from the oscillator 115.

It should be noted that the timing circuit 164 is not limited to the configuration above mentioned.

### (Layout of the Semiconductor Device)

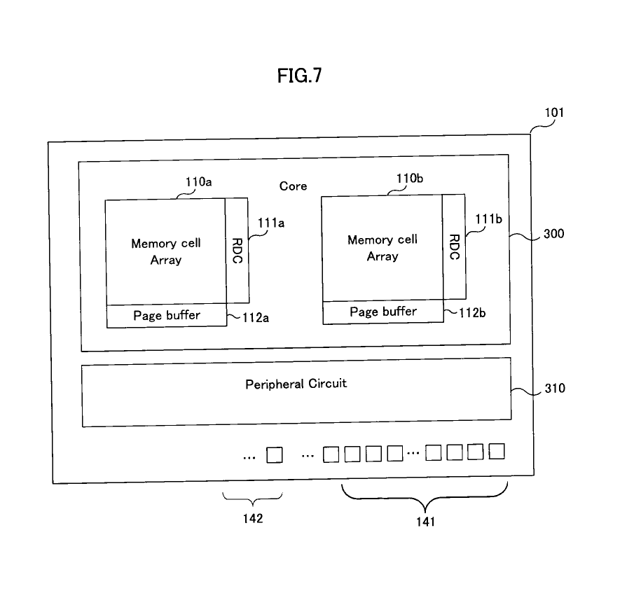

FIG. 7 is a block diagram showing the configuration of the semiconductor device of the second embodiment. The semiconductor device 101 includes a core 300, a peripheral circuit 310, and a plurality of pads 141, 142. The core includes a plurality of memory cell arrays 110a, 110b, row decoders (RDC) 111a, 111b, and page buffers 112a, 112b.

The peripheral circuit 310 includes a controller 103, an ECC (Error Checking and Correcting) section 104, an interface section 105, a test circuit 106, a voltage generator circuit 113, a NAND sequencer 114, oscillators (OSC) 115, 116, a data transfer part 117 and a trimming circuit 118. The peripheral circuit 310 is adjacent to the core 300.

The plurality of pads 141, 142 are disposed in a line for example. The plurality of pads 141 are different from the plurality of pads 142. The plurality of pads 141 are disposed separately from the plurality of pads 142.

### (Test Operation)

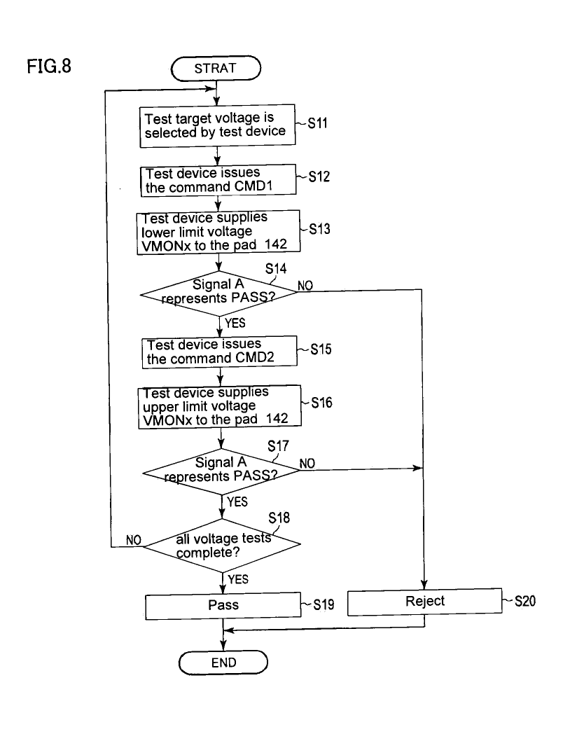

FIG. 8 shows how the test device 100 operates. Referring to FIG. 8, descriptions will be provided for the operation of the test circuit 106 shown in FIGS. 5 and 6.

As described above, when the voltages generated by the voltage generator circuit 113 of the semiconductor device are tested in the process of manufacturing the semiconductor device, the wafer on which the semiconductor device is formed is attached to the test device 100, and the probes of the test device 100, which are not illustrated, are brought into contact with the pads 141, 142 of the semiconductor device 101.

In this state, a test target voltage is selected by the test device 100 (in step S11). As described above, this voltage is any one of the voltages VREF, VPASS, VREAD, etc. In this respect, the voltage VREF is a reference voltage; the voltage VPASS is a voltage for turning on non-selected memory cells during the write-operation performed on the NAND flash memory; and the voltage VREAD is a voltage for turning on non-selected memory cells during the read operation. In this step, let us assume that the reference voltage VREF is selected.

Any one of the voltages VREF, VPASS, VREAD is selected in sequence. For example the voltage is selected after following steps from S11 to S20 are executed as to the reference voltage VREF,

Next, the test device 100 issues the command CMD1 for testing the lower limit value of the selected voltage VREF (in S12). In this respect, the command CMD1 is a command for performing the test operation, and includes: a part for indicating a voltage to be tested; and a part for indicating which of the upper limit value and the lower limit value of the voltage is to be tested.

This command CMD1 is supplied to the pad 141, the interface 131, the register 151, the CUI 152, the state machine 153 and the address/command generator circuit 54 of the semiconductor device 101 shown in FIG. 5. On the basis of the command CMD1, the address/command generator circuit 154 generates the internal command CMD_OVMON (“1”). This internal command CMD_OVMON is supplied to the trimming circuit 118. When the internal command CMD_OVMON represents “1,” the trimming circuit 118 does not perform the trimming operation. For this reason, on the basis of the signal Param_IN, the voltage venerator circuit 113 generates the voltage VREF of 1.1V in accordance with a pre-set parameter. This generated voltage VREF is supplied to the first internal input of the comparator 61.

It should be noted that in a case where the power supply is cut off between the trimming test and the test of this embodiment, a parameter having been set in the trimming test is set as the foregoing parameter when the power ON is reset. In addition, in a case where the trimming test and the test of this embodiment are carried out consecutively without cutting off the power supply between the trimming test and the test of this embodiment, the test of this embodiment is carried out with the parameter, which has been set in the trimming test, remaining unchanged.

Next, the test device 100 generates the lower limit monitor voltage VMONx with respect to the test target voltage, and supplies the lower limit voltage to the pad 142 of the semiconductor device 101 (in step S13). In other words, in this example, the test device 100 supplies the lower limit voltage (1.1V) of the voltage VREF (1.2V), as the lower limit monitor voltage VMONx, to the pad 142. This lower limit monitor voltage VMONx is supplied to the second input terminal of the comparator 161 via the pad 142.

The comparator 161 compares the lower limit monitor voltage VMONx and the voltage VREF generated by the voltage generator circuit 113. If as a result of this, the relationship expressed with VMONx (1.1V)<VREF (1.2V) is satisfied, the comparator 61 outputs a signal “0” as the output signal FLGTRIML. This signal FLGTRIML is supplied to the data inversion circuit 162. If the internal command CMD_OVMON represents “1,” the data inversion circuit 162 inverts the inputted signal, and outputs the inverted signal. For this reason, the signal FLGTRIML=“0” is inverted, and the data inversion circuit 162 outputs the status signal A=“1” which indicates that the test result is PASS. This signal A=“1” is once held in the status holding circuit 163.

On the other hand, if as a result of the comparison, the relationship expressed with VMONx (1.1V)<VREF (1.2V) is not satisfied, the comparator 61 outputs a signal “1” as the output signal FLGTRIML. This signal FLGTRIML is inverted by the data inversion circuit 162, and is thus outputted from the data inversion circuit 162. For this reason, the signal FLGTRIML=“1” is inverted, and the data inversion circuit 162 outputs the status signal A=“0” which indicates that the test result is FAIL. This signal A=“0” is once held in the status holding circuit 163. In other words the semiconductor device holds the signal A which stands for PASS or FAIL of the test result.

Once a status read command is issued from the test device 100, the status signal A which is held in the status holding circuit 163, and which indicates that the test result is PASS or FAIL, is read out and is applied to the test device 100 via the interface 131 and the pad 141.

The test device 100 judges whether or not the status signal A represents PASS (in step S14). If as a result of this, the status signal A represents FAIL, the semiconductor device 101 is rejected, and the test operation is terminated (in step S20).

On the other hand, if the status signal A represents PASS, the test device 100 issues the command CMD2 for testing the upper limit voltage of the selected voltage (in step S15).

This command CMD2 is supplied to the address/command generator circuit 154 via the pad 141, the interface 131, the register 151, the command/user interface 152 and the state machine 153 of the semiconductor device 101 shown in FIG. 5. On the basis of the supplied command, this address/command generator circuit 154 generates the command CMD_UVMON (“1”) for testing the upper limit voltage. This internal command CMD_UVMON is supplied to the trimming circuit 118. When the internal command CMD_UVMON represents “1,” the trimming circuit 118 does not perform the trimming operation. For this reason, on the basis of the signal Param_IN, the voltage venerator circuit 113 generates the voltage VREF of 1.3V in accordance with a pre-set parameter. This generated voltage VREF is supplied to the first internal input of the comparator 161.

Next, the test device 100 generates the upper limit monitor voltage VMONx with respect to the test target voltage, and supplies the upper limit voltage to the pad 142 of the semiconductor device 1 (in step S16). In other words, in this example, the test device 100 supplies the upper limit voltage (1.3V) of the voltage VREF (1.2V), as the upper limit monitor voltage VMONx, to the pad 142. This upper limit monitor voltage VMONx is supplied to the second input terminal of the comparator 161 via the pad 142.

The comparator 161 compares the upper limit monitor voltage VMONx and the voltage VREF generated by the voltage generator circuit 113. If as a result of this, the relationship expressed with VMONx (1.3V)>VREF (1.2V) is satisfied, the comparator 161 outputs a signal “1” as the output signal FLGTRIML. This signal FLGTRIML is supplied to the data inversion circuit 162. If the internal command CMD_UVMON represents “1,” the data inversion circuit 162 outputs the received data, as it is, without inverting the received data. For this reason, the data inversion circuit 162 outputs the status signal A=“1” which indicates that the test result is PASS. This signal A=“1” is once held in the status holding circuit 163.

On the other hand, if as a result of the comparison, the relationship expressed with VMONx (1.3V)>VREF (1.2V) is not satisfied, the comparator 161 outputs a signal “0” as the output signal FLGTRIML. This signal FLGTRIML is also outputted, as it is, from the data inversion circuit 162 without being inverted by the data inversion circuit 162. For this reason, the data inversion circuit 162 outputs the status signal A=“0” which indicates that the test result is FAIL. This status signal A=“0” is once held in the status holding circuit 163.

Once a status read command is issued from the test device 100, the status signal A which is held in the status holding circuit 163, and which indicates that the test result is PASS or FAIL, is read out and is supplied to the test device 100 via the interface 131 and the pad 141.

Subsequently, the test device 100 judges whether or not the status signal A represents PASS (in step S17). If as a result of this, the status signal A represents FAIL, the semiconductor device 1 is rejected, and the test operation is terminated (in step S20).

On the other hand, if the status signal A represents PASS, it is judged whether or not all the voltage tests have been completed (in step S18). If as a result of this, all the voltage tests have not been completed yet, the control proceeds to step S11, a test target voltage next is selected, and the operation similar to what has been described above will be repeated.

In addition, if it is judged in step S18 that all the voltage tests have been completed, it is judged that the semiconductor device 1 passes the voltage tests (in step S19).

The above steps are executed when the reference voltage VREF is selected. After the above steps about the reference voltage VREF are finished, for example the voltage VPASS is selected. The above steps about the voltage VPASS (from S11 to S20) are executed after the flip-flop circuit 164a and the status holding circuit 163 are reset. In other words every time the above steps (from S11 to S20) are finished, the flip-flop circuit 164a and the status holding circuit 163 are reset. All of the test results may be held in the second embodiment of the semiconductor device.

### (Test Device)

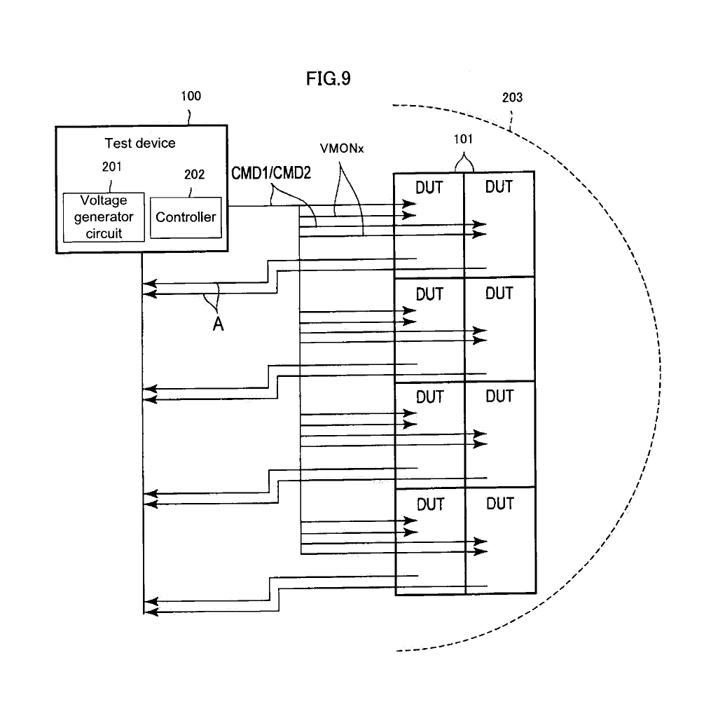

FIG. 9 shows a relationship between the test device 100 and multiple semiconductor devices (semiconductor chips) as DUT (Devices Under Test).

As shown in FIG. 9, the test device 100 includes a voltage generator circuit 201 and a controller 202. The controller 202 supplies the command CMD1 or the command CMD2 to the multiple semiconductor devices 101 provided in a wafer 203 at the same time, and supplies the monitor voltage VMONx as a voltage of the lower or upper limit value of a test target voltage generated by the voltage generator circuit 201, to the multiple semiconductor devices 101 at the same time. In the inside of each semiconductor device 1, the monitor voltage VMONx and the voltage venerated by the voltage venerator circuit 113 are compared by the comparator 161, and as the status signal A, the result of the comparison is held in the status holding circuit 163. The status signals A held by the status holding circuits 163 in the respective semiconductor devices 101 are taken into the test device 100 at the same time, once the status read command is issued from the controller 202. The controller 202 judges whether each status signal A represents PASS or FAIL.

Unlike general test devices, the test device 100 does not need multiple measurement circuits for measuring the voltages outputted from the respective semiconductor devices. For this reason, the configuration of the test device 100 can be simplified. Furthermore, because the test device 100 is capable of testing the multiple semiconductor devices 101 at the same time, the test device 100 makes it possible to reduce time needed for the test.

In the foregoing embodiment, the comparator 161 is provided in the inside of each semiconductor device 1; the test target voltage which is generated by the voltage generator circuit 113 in the semiconductor device 101 and the monitor voltage VMONx supplied from the test device 100 are compared by the comparator 161; and as the status signal A, the result of this comparison is supplied to the test device 100. For this reason, the semiconductor device 101 does not supply the voltage, which is generated by the voltage generator circuit 113, to the test device 100, but supplies the status signal, which shows the result of the comparison, to the test device 100; and the test device 100 does not compare the voltage supplied from the semiconductor device 101 and the specific values in order to judge whether the supplied voltage falls within the range between the specific values, but judges whether the status signal supplied from the semiconductor device 101 is PASS or FAIL. Accordingly, the configuration of the test device can be simplified, and the time needed for the test can be reduced.

To put it specifically, in this embodiment, for the test, the semiconductor device 101 receives the command CMD1 indicating the test target voltage and its lower limit value, or the command CMD2 indicating the test target voltage and its upper limit value, from the test device 100; in addition, the semiconductor device 101 receives the lower limit voltage VMONx indicating the lower limit value of the test target voltage, or the upper limit voltage VMONx indicating the upper limit value of the test target voltage, from the test device 100; the semiconductor device 101 causes the comparator 161 to compare the voltage outputted from the voltage generator circuit 113 with the lower limit or upper limit voltage VMONx; and the semiconductor device 101 supplies the result of this comparison, as the status signal, to the test device. For this reason, unlike general test devices, the test device does not need the test circuits for: receiving the test target voltages from the multiple semiconductor devices 101; and judging whether or not each voltage falls within the range between the specified upper and lower limit values. For this reason, the configuration of the test device can be simplified.

Furthermore, in the case of the general test devices, the number of test circuits is smaller than the number of semiconductor chips on a wafer. For this reason, when the voltages supplied from the respective semiconductor devices are tested in the test device, the test device needs to test the voltages supplied from parts of the semiconductor devices included in the wafer on a one-by-one basis. For this reason, it takes longer time to test the voltages supplied from all the semiconductor devices.

By contrast, in this embodiment, each semiconductor device 1 has the test circuit 106 in its inside; as shown in FIG. 8, the command and the corresponding voltage are supplied from the test device 100 to all the semiconductor devices at the same time; and the status signals A outputted from the respective semiconductor devices can be taken into the test device 100 at the same time. Accordingly, the time needed for the test can be largely reduced.

Moreover, the monitor voltages VMONx outputted from the respective test devices 100 vary little from one test device to another. For this reason, in a case where multiple wafers are tested by use of multiple test devices at the same time, all the semiconductor device can be tested by use of correct voltages outputted from the respective test devices. Accordingly, an accurate test can be carried out.

In addition, the data inversion circuit 162 of each semiconductor device 101 inverts the result (the signal FLGTRIML) of the comparison by the comparator 161 between the voltage outputted from the voltage generator circuit 113 and the lower limit monitor voltage VMONx, and supplies the inverted result to the status holding circuit 163. However, the data inversion circuit 162 does not invert the result (the signal FLGTRIML) of the comparison by the comparator 161 between the voltage outputted from the voltage generator circuit 113 and the upper limit monitor voltage VMONx, and supplies the result to the status holding circuit 163. For these reason, the status holding circuit 163 is capable of holding both of the results of testing the lower limit value and the upper limit value of the test target voltage as the status signal A=“1.” Accordingly, the test device is capable of handling both of the PASS results of testing the upper limit value and the lower limit value as the status signal A=“1.” Thus, the judgment on PASS or FAIL can be carried out quickly.

Furthermore, the data inversion circuit 162 is formed from the selection circuit 162a including: the first input terminal to which the output signal from the comparator 161 is supplied; and the second input terminal to which the inversion of the output signal from the comparator 161 is supplied. On the basis of the internal command CMD_UVMON, the selection circuit 162a outputs the signal supplied to the first input terminal. On the basis of the internal command CMD_OVMON, the selection circuit 162a outputs the signal supplied to the second input terminal. For these reason, the data on the result of the comparison for the lower limit value can be inverted by use of the simple configuration.

It should be noted that although the foregoing descriptions have been provided for the embodiments which are applied to the NAND flash memory, the present invention is not limited to these embodiments. It is the matter of course that the present invention can be applied to semiconductor devices which are designed to generate various voltages in their insides.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. We may combine the semiconductor memory device of the first embodiment with the second embodiment.

### (Appendance 1)

A semiconductor memory device comprising:

memory cells;

a memory cell array including blocks, each block including a plurality of pages, each page including a plurality of the memory cells;

a first storage for holding a first repetition count when data is written into a first memory cell belonging to a first column in each of the pages, the first repetition count indicating the number of times the first memory cell has been programmed so far,

a second storage for holding a second repetition count when data is written to a second memory cell belonging to a second column different from the first column in the page, the second repetition count indicating the number of times the second memory cell has been programmed so far; and

a controller for registering a block, which includes the first memory cell and the second memory cell, as a defective block when a difference between the first repetition count and the second repetition count exceeds a specified value.

### (Appendance 2)

The semiconductor memory device as recited in appendance 1, wherein in the page, a memory cell situated in one end is defined as the first memory cell.

### (Appendance 3)

The semiconductor memory device as recited in appendance 2, wherein in the page, a memory cell situated in an opposite end is defined as the second memory cell.

### (Appendance 4)

A semiconductor memory device comprising:

memory cells;

a memory cell array including blocks, each block including a plurality of pages, and each page including a plurality of the memory cells;

a first storage for holding a first repetition count when data is written into a first memory cell group belonging to a first column group in each of the pages, the first repetition count indicting the number of times the memory cells of the first memory cell group have been programmed so far;

a second storage for holding a second repetition count when data is written into a second memory cell group belonging to a second column group in the page, the second repetition count indicating the number of times the memory cells in the second memory group have been programmed so far; and

a controller for registering a block, which includes the first memory cell group and the second memory cell group, as a defective block when a difference between the first repetition count and the second repetition count exceeds a specified value.

### (Appendance 5)

The semiconductor memory device as recited in appendance 4, wherein

in the page, a memory cell group situated in one end portion is defined as the first memory cell group, and

in the page, a memory cell group situated in an opposite end portion is defined as the second memory cell group.

### (Appendance 6)

A semiconductor device comprising:

a first pad for receiving first and second test commands supplied from a test device;

a voltage generator circuit for generating a test target voltage on the basis of the first and second test commands supplied to the first pad;

a second pad for receiving a first monitor voltage supplied from the test device in response to the first test command and a second monitor voltage supplied from the test device in response to the second test command, the first monitor voltage corresponding to a lower limit voltage of the test target voltage, the second monitor voltage corresponding to an upper limit voltage of the test target voltage;

a comparator for outputting a first output signal at one of first and second logical levels by comparing the test target voltage supplied from the voltage generator circuit, with the first monitor voltage supplied via the second pad, and for outputting a second output signal at one of the first and second logical levels by comparing the test target voltage supplied from the voltage generator circuit, with the second monitor voltage supplied via the second pad; and

a data inverter for inverting the first output signal from the comparator and supplying the inverted signal to the first pad on the basis of the first test command, and for outputting the second output signal from the comparator without inverting the output signal on the basis of the second test command.

### (Appendance 7)

A semiconductor device including a plurality of semiconductor devices connected to a test device, each of the semiconductor devices comprising:

a first pad for receiving first and second test commands which are supplied from the test device;

a voltage generator circuit for generating a test target voltage on the basis of the first and second test commands supplied to the first pad;

a second pad for receiving a first monitor voltage supplied from the test device in response to the first test command and a second monitor voltage supplied from the test device in response to the second test command, the first monitor voltage corresponding to a lower limit voltage of the test target voltage, the second monitor voltage corresponding to a upper limit voltage of the test target voltage;

a comparator for outputting an output signal at one of first and second logical levels by comparing the test target voltage supplied from the voltage generator circuit, with the first monitor voltage supplied via the second pad, and for outputting an output signal at one of the first and second logical levels by comparing the test target voltage supplied from the voltage generator circuit, with the second monitor voltage supplied via the second pad; and

a data inverter for inverting the output signal from the comparator and supplying the inverted signal to the first pad on the basis of the first test command, and for outputting the output signal from the comparator without inverting the output signal on the basis of the second test command.

### (Appendance 8)

The semiconductor device as recited in any one of appendances 6 and 7, wherein

the data inverter includes a selection circuit including: a first input terminal supplied with the output signal from the comparator; and a second input terminal supplied with the inverted signal of the output signal from the comparator,

on the basis of the first test command, the selection circuit selects and outputs the signal supplied to the second input terminal, and

on the basis of the second test command, the selection circuit selects and outputs the signal which is supplied to the first input terminal.

### (Appendance 9)

The semiconductor device as recited in appendance 8, further comprising a holding part for holding a first status signal outputted from the data inverter on the basis of the first test command, and a second status signal outputted from the data inverter on the basis of the second test command, wherein

the first and second status signals held by the holding part are read out and supplied to the test device in response to a command supplied from the test device.

### (Appendance 10)

A test system comprising:

a test device including
a first voltage generator circuit for generating a first monitor voltage for monitoring a lower limit voltage of a test target voltage in a semiconductor device, and a second monitor voltage for monitoring an upper limit voltage of the test target voltage in the semiconductor device;
a controller for issuing a first test command for testing the lower limit voltage, and a second test command for testing the upper limit voltage, wherein

the controller
supplies the first test command for testing the lower limit voltage and the first monitor voltage to the semiconductor device,
judges whether the first status signal supplied from the semiconductor device is PASS or FAIL,
supplies the second test command and the second monitor voltage to the semiconductor device if the first status signal is PASS, and
judges whether the second status signal supplied from the semiconductor device is PASS or FAIL;

a first pad for receiving the first and second test commands supplied from the test device;

a second pad for receiving the first and second monitor voltages supplied from the test device;

a second voltage generator circuit for generating the test target voltage on the basis of the first and second test commands supplied to the first pad; and

a comparator for outputting an output signal at one of first and second logical levels, as the first status signal, by comparing the test target voltage supplied from the second voltage generator circuit, with the first monitor voltage supplied via the second pad, and for outputting an output signal at one of the first and second logical levels, as the second status signal, by comparing the test target voltage supplied from the second voltage generator circuit, with the second monitor voltage supplied via the second pad.

### (Appendance 11)

The test system as recited in appendance 10, further comprising a data inverter for inverting the output signal from the comparator and supplying the inverted signal to the first pad on the basis of the first test command, and for outputting the output signal from the comparator without inverting the output signal on the basis of the second test command.

### (Appendance 12)

The test system as recited in appendance 11, further comprising a holding part for holding the first or second status signal supplied from the data inverter, wherein

the first or second status signal held by the holding part is read out and supplied to the test device in response to a command supplied from the test device.

### (Appendance 13)

A test device comprising:

a voltage generator circuit for generating a first monitor voltage for monitoring a lower limit voltage of a test target voltage in a semiconductor device, and a second monitor voltage for monitoring a upper limit voltage of the test target voltage in the semiconductor device; and

a controller for issuing a first test command for testing the lower limit voltage, and a second test command for testing the upper limit voltage, wherein

the controller
supplies the first test command for testing the lower limit voltage and the first monitor voltage to the semiconductor device,
judges whether the first status signal supplied from the semiconductor device is PASS or FAIL,
supplies the second test command and the second monitor voltage to the semiconductor device if the first status signal is PASS, and
judges whether the second status signal supplied from the semiconductor device is PASS or FAIL.

### (Appendance 14)

A semiconductor device comprising:

a first pad for receiving first and second test commands supplied from a test device;

a second pad for receiving first and second monitor voltages supplied from the test device;

a voltage generator circuit for generating a test target voltage on the basis of the first and second test commands supplied to the first pad; and

a comparator for outputting an output signal at one of first and second logical levels, as the first status signal, by comparing the test target voltage supplied from the voltage generator circuit, with the first monitor voltage supplied via the second pad, and for outputting an output signal at one of the first and second logical levels, as the second status signal, by comparing the test target voltage supplied from the second voltage generator circuit, with the second monitor voltage supplied via the second pad.

### (Appendance 15)

The semiconductor device as recited in appendance 14, further comprising a data inverter for inverting the output signal from the comparator and supplying the inverted signal to the first pad on the basis of the first test command, and for outputting the output signal from the comparator without inverting the output signal on the basis of the second test command.

### (Appendance 16)

The semiconductor device as recited in appendance 15,

further comprising a holding part for holding the first or second status signal supplied from the data inverter, wherein

the first or second status signal held by the holding part is read out and supplied to the test device in response to a command supplied from the test device.

### (Appendance 17)

A method of manufacturing a semiconductor device comprising:

receiving first and second test commands supplied from outside;

generating a test target voltage on the basis of the first and second test commands;

receive a first monitor voltage supplied from outside in response to the first test command and a second monitor voltage supplied from outside in response to the second test command, the first monitor voltage corresponding to a lower limit voltage of the test target voltage, the second monitor voltage corresponding to an upper limit voltage of the test target voltage;

outputting a first output signal at one of first and second logical levels by comparing the test target voltage, with the first monitor voltage; and

outputting a second output signal at one of the first and second logical levels by comparing the test target voltage, with the second monitor voltage.

### (Appendance 18)

The method of manufacturing a semiconductor device of appendance 18, further comprising:

inverting the first output signal from a comparator, the comparator being configured to compare the test target voltage with the first monitor voltage or to compare the test target voltage with the second monitor voltage;

supplying the inverted signal on the basis of the first test command;

outputting the second output signal from the comparator without inverting the output signal on the basis of the second test command.

What is claimed is:

1. A semiconductor device comprising:
a first pad configured to receive first and second test commands supplied from outside;
a voltage generator circuit for generating a test target voltage on the basis of the first and second test commands;
a second pad configured to receive a first monitor voltage supplied from outside in response to the first test command and a second monitor voltage supplied from outside in response to the second test command, the first monitor voltage corresponding to a lower limit voltage of the test target voltage, the second monitor voltage corresponding to an upper limit voltage of the test target voltage; and
a comparator configured to output a first output signal at one of first and second logical levels by comparing the test target voltage supplied from the voltage generator circuit, with the first monitor voltage, the comparator being configured to output a second output signal at one of the first and second logical levels by comparing the test target voltage supplied from the voltage generator circuit, with the second monitor voltage.

2. The semiconductor device of claim 1, further comprising:
a data inverter configured to invert the first output signal from the comparator and to supply the inverted signal to the first pad on the basis of the first test command, the data inverter being configured to output the second output signal from the comparator without inverting the output signal on the basis of the second test command.

3. The semiconductor device of claim 2, further comprising:
a holding part configured to hold the first or second status signal supplied from the data inverter, wherein the first or second status signal held by the holding part is read out and supplied to outside in response to a command supplied from outside.

4. The semiconductor device of claim 1 comprising a plurality of semiconductor devices connected to outside, each of the semiconductor devices including the first pad, the voltage generator circuit, the second pad, and the comparator.

5. The semiconductor device of claim 2 comprising a plurality of semiconductor devices connected to outside, each of the semiconductor devices including the first pad, the voltage generator circuit, the second pad, and the comparator.

6. The semiconductor device of claim 2, wherein
the data inverter includes a selection circuit including: a first input terminal supplied with the output signal from the comparator; and a second input terminal supplied with the inverted signal of the output signal from the comparator,
on the basis of the first test command, the selection circuit selects and outputs the signal supplied to the second input terminal, and
on the basis of the second test command, the selection circuit selects and outputs the signal which is supplied to the first input terminal.

7. The semiconductor device of claim 3, wherein
the data inverter includes a selection circuit including: a first input terminal supplied with the output signal from the comparator; and a second input terminal supplied with the inverted signal of the output signal from the comparator,
on the basis of the first test command, the selection circuit selects and outputs the signal supplied to the second input terminal, and
on the basis of the second test command, the selection circuit selects and outputs the signal which is supplied to the first input terminal.

8. The semiconductor device of claim 5, wherein
the data inverter includes a selection circuit including: a first input terminal supplied with the output signal from the comparator; and a second input terminal supplied with the inverted signal of the output signal from the comparator,
on the basis of the first test command, the selection circuit selects and outputs the signal supplied to the second input terminal, and
on the basis of the second test command, the selection circuit selects and outputs the signal which is supplied to the first input terminal.

9. A operation method of semiconductor device comprising:
receiving first and second test commands supplied from outside, the first test command being for testing the lower limit voltage, the second test command being for testing the upper limit voltage;
receiving first and second monitor voltages supplied from the outside, the first monitor voltage being for monitoring a lower limit voltage of a test target voltage in the semiconductor device, the second monitor voltage being for monitoring an upper limit voltage of the test target voltage in the semiconductor device;
generating the test target voltage on the basis of the first and second test commands;
outputting an output signal at one of first and second logical levels, as the first status signal, by comparing the test target voltage, with the first monitor voltage;
outputting an output signal at one of the first and second logical levels, as the second status signal, by comparing the test target voltage, with the second monitor voltage.

10. A test system comprising:
a test device including
a first voltage generator circuit for generating a first monitor voltage for monitoring a lower limit voltage of a test target voltage in a semiconductor device, and a second monitor voltage for monitoring an upper limit voltage of the test target voltage in the semiconductor device;
a controller for issuing a first test command for testing the lower limit voltage, and a second test command for testing the upper limit voltage,
wherein the controller supplies the first test command for testing the lower limit voltage and the first monitor voltage to the semiconductor device, judges whether the first status signal supplied from the semiconductor device is PASS or FAIL, supplies the second test command and the second monitor voltage to the semiconductor device if the first status signal is PASS, and judges whether the second status signal supplied from the semiconductor device is PASS or FAIL; a first pad for receiving the first and second test commands supplied from the test device; a second pad for receiving the first and second monitor voltages supplied from the test device; a second voltage generator circuit for generating the test target voltage on the basis of the first and second test commands supplied to the first pad; and
a comparator for outputting an output signal at one of first and second logical levels, as the first status signal, by comparing the test target voltage supplied from the second voltage generator circuit, with the first monitor voltage supplied via the second pad, and for outputting an output signal at one of the first and second logical levels, as the second status signal, by comparing the test target voltage supplied from the second voltage generator circuit, with the second monitor voltage supplied via the second pad.

11. The test system of claim 10, further comprising a data inverter for inverting the output signal from the comparator and supplying the inverted signal to the first pad on the basis of the first test command, and for outputting the output signal from the comparator without inverting the output signal on the basis of the second test command.

12. The test system of claim 11, further comprising a holding part for holding the first or second status signal supplied from the data inverter, wherein the first or second status signal held by the holding part is read out and supplied to the test device in response to a command supplied from the test device.
